(19) United States
(12) Patent Application Publication
(10) Pub. No.: US 2024/0319605 A1
(43) Pub. Date: Sep. 26, 2024

(54) HARDMASK COMPOSITION, HARDMASK LAYER AND METHOD OF FORMING PATTERNS

(71) Applicant: SAMSUNG SDI CO., LTD., Yongin-si (KR)

(72) Inventors: Hyeonil Jung, Suwon-si (KR); Youngmin Kim, Suwon-si (KR); Yejin Kim, Suwon-si (KR); Soyeon Park, Suwon-si (KR); Sunyoung Yang, Suwon-si (KR); Shinhyo Bae, Suwon-si (KR); Sungeun Lee, Suwon-si (KR); Hyungseok Park, Suwon-si (KR); Chaerin Song, Suwon-si (KR)

(21) Appl. No.: 18/413,619

(22) Filed: Jan. 16, 2024

(30) Foreign Application Priority Data
Mar. 21, 2023 (KR) 10-2023-0036795

(51) Int. Cl. G03F 7/20

(52) U.S. Cl. CPC G03F 7/202

(57) ABSTRACT

A hardmask composition, a hardmask layer including a cured product of the hardmask composition, and a method of forming patterns using the hardmask layer manufactured from the hardmask composition, the hardmask composition includes a polymer including a structural unit represented by Chemical Formula 1; and a solvent,

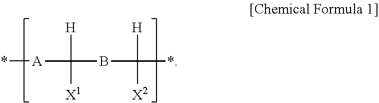

### CROSS-REFERENCE TO RELATED APPLICATION

This application claims priority to and the benefit of Korean Patent Application No. 10-2023-0036795 filed in the Korean Intellectual Property Office on Mar. 21, 2023, the entire contents of which are incorporated herein by reference.

### BACKGROUND

### 1. Field

Embodiments relate to a hardmask composition, a hardmask layer, and a method of forming patterns.

### 2. Description of the Related Art

Recently, the semiconductor industry has developed to an ultra-fine technique having a pattern of several to several tens nanometer size. Such ultrafine technique may use effective lithographic techniques. Some lithographic techniques may include providing a material layer on a semiconductor substrate; coating a photoresist layer thereon; exposing and developing the same to provide a photoresist pattern; and etching a material layer using the photoresist pattern as a mask. Nowadays, according to small-sizing the pattern to be formed, it may be difficult to provide a fine pattern having an excellent profile by only using such typical lithographic techniques. Accordingly, an auxiliary layer, called a hardmask layer, may be formed between the material layer and the photoresist layer to provide a fine pattern.

### SUMMARY

The embodiments may be realized by providing a hardmask composition including a polymer including a structural unit represented by Chemical Formula 1; and a solvent:

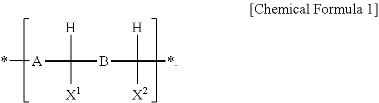

wherein, in Chemical Formula 1, A includes a moiety represented by Chemical Formula 2, B includes a substituted or unsubstituted moiety of Group 1, X¹ and X² each independently include a substituted or unsubstituted moiety of Group 2, and * is a linking point,

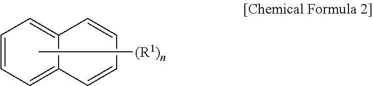

wherein, in Chemical Formula 2, R¹ is a hydroxy group, an amine group, a thiol group, or —OR^{a}, in which R^{a} is a substituted or unsubstituted C1 to C30 alkyl group, a substituted or unsubstituted C2 to C30 alkenyl group, a substituted or unsubstituted C2 to C30 alkynyl group, or a substituted or unsubstituted C6 to C30 aryl group, and n is an integer of 2 to 6,

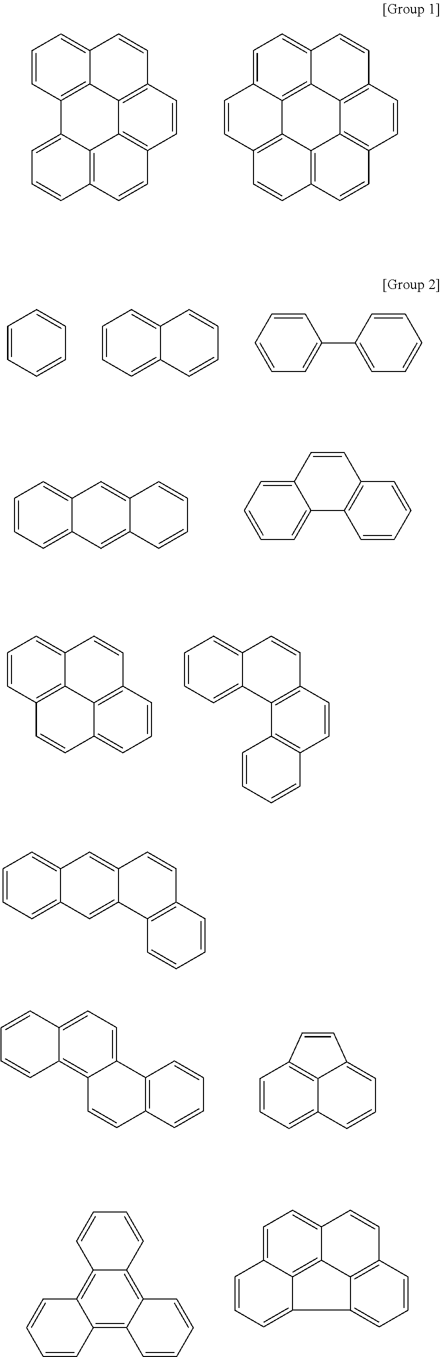

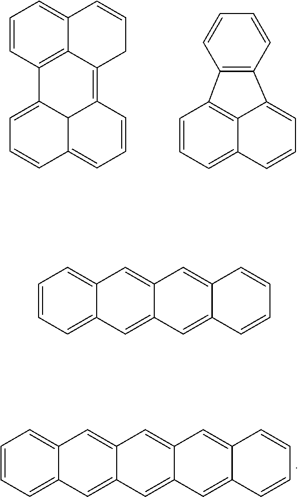

In Chemical Formula 2, R¹ may be a hydroxy group, an amine group, a thiol group, or —OR^{a}, in which, R^{a} is a substituted or unsubstituted C1 to C20 alkyl group, a substituted or unsubstituted C2 to C20 alkenyl group, a substituted or unsubstituted C2 to C20 alkynyl group, or a substituted or unsubstituted C6 to C20 aryl group, and n may be an integer of 2 to 4.

In Chemical Formula 2, R¹ may be a hydroxy group or —OR^{a}, in which R^{a} is a substituted or unsubstituted C1 to C10 alkyl group, a substituted or unsubstituted C2 to C10 alkenyl group, a substituted or unsubstituted C2 to C10 alkynyl group, or a substituted or unsubstituted C6 to C16 aryl group, and n may be 2 or 3.

A of Chemical Formula 1 may include a moiety represented by one of Chemical Formula 2-1 to Chemical Formula 2-3:

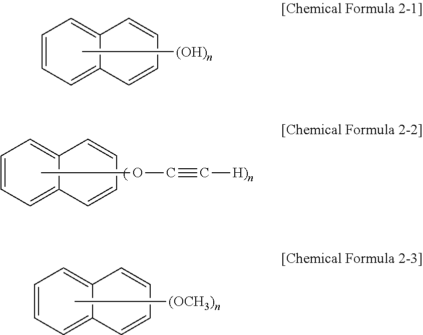

in Chemical Formula 2-1 to Chemical Formula 2-3, n may be 2 or 3.

B of Chemical Formula 1 may include an unsubstituted moiety of Group 1.

B of Chemical Formula 1 may include a substituted moiety of Group 1, and a substituent of the substituted moiety of Group 1 may include a hydroxy group, a halogen atom, a substituted or unsubstituted C1 to C20 alkoxy group, a substituted or unsubstituted C1 to C20 alkyl group, a substituted or unsubstituted C2 to C20 alkenyl group, a substituted or unsubstituted C2 to C20 alkynyl group, or a combination thereof.

In Chemical Formula 1, X¹ and X² may each independently include a substituted or unsubstituted moiety of Group 2-1:

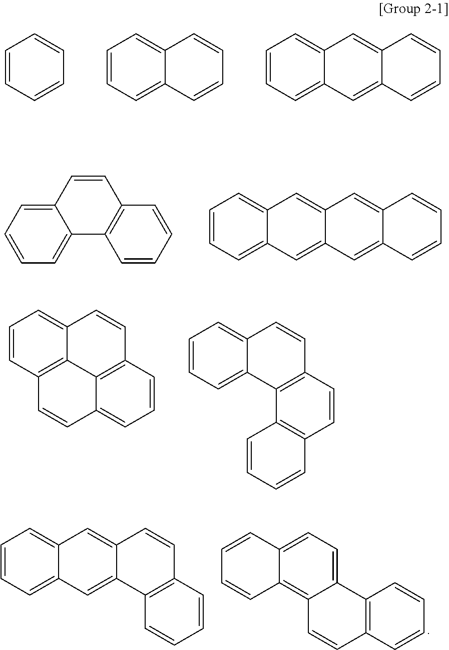

In Chemical Formula 1, X¹ and X² may each independently include a substituted or unsubstituted moiety of Group 2-2:

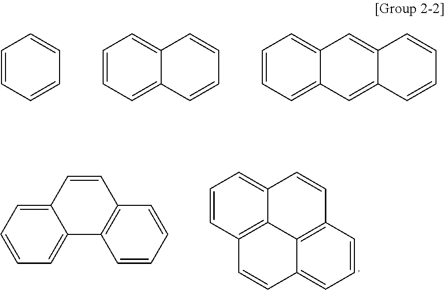

The structural unit represented by Chemical Formula 1 may be represented by one of Chemical Formula 1-1 to Chemical Formula 1-6:

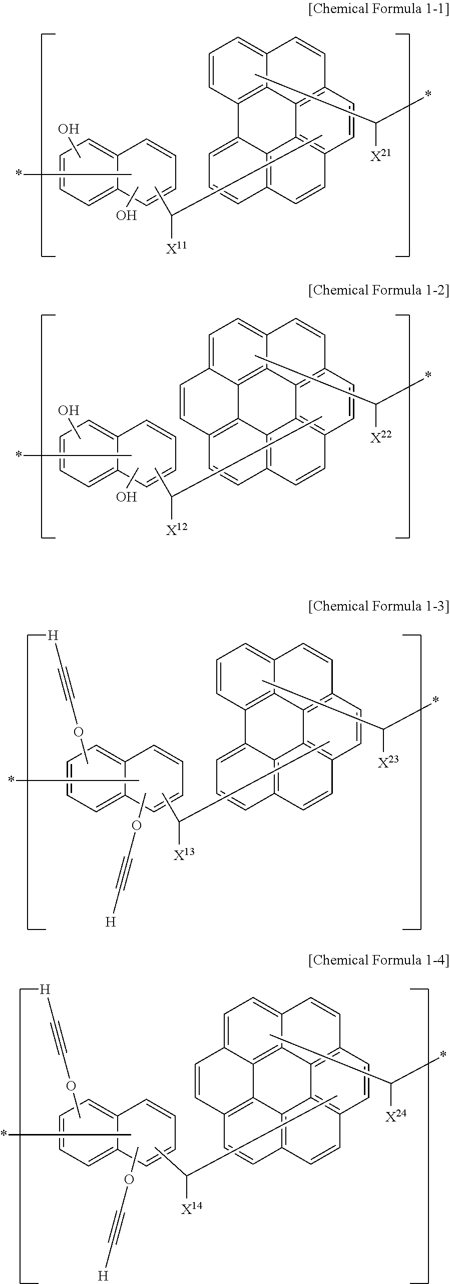

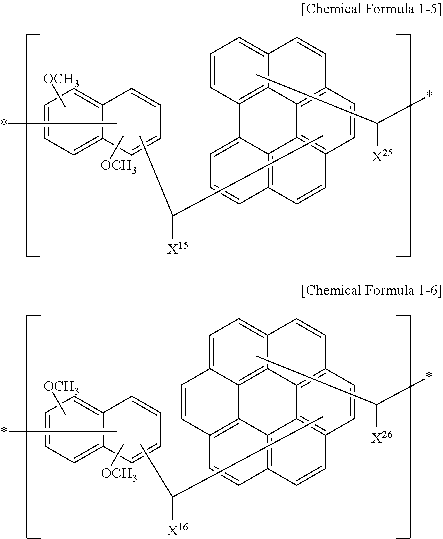

in Chemical Formula 1-1 to Chemical Formula 1-6, X¹¹ to X¹⁶ and X²¹ to X²⁶ may each independently include a substituted or unsubstituted moiety of Group 2-2:

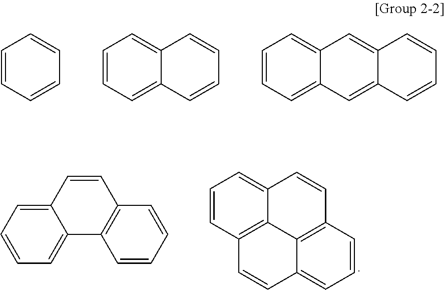

The structural unit represented by Chemical Formula 1 may be represented by one of Chemical Formula 1-7 to Chemical Formula 1-10:

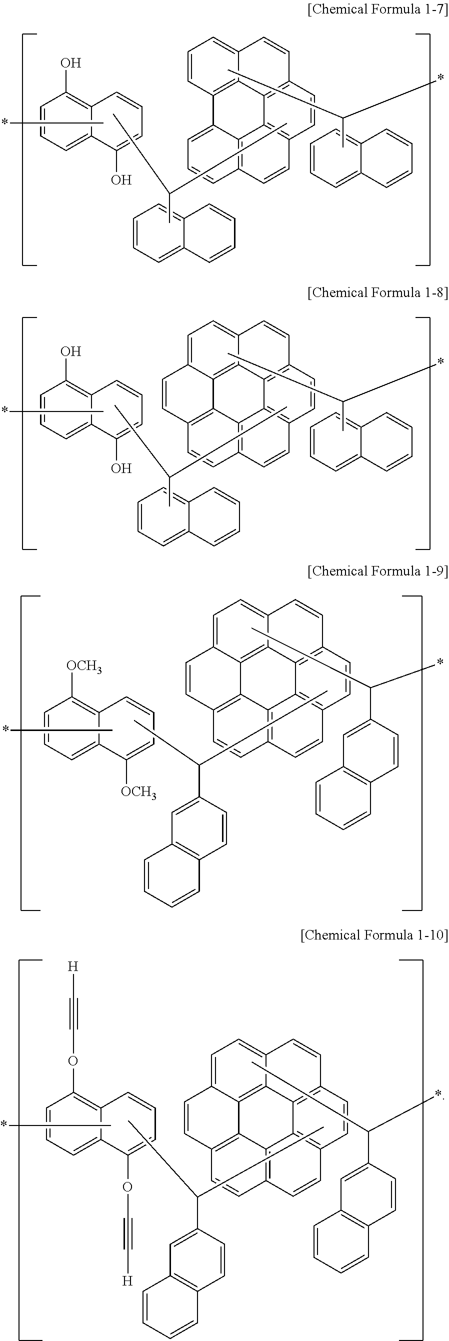

The polymer may have a weight average molecular weight of about 1,000 g/mol to about 200,000 g/mol.

The polymer may be included in an amount of about 0.1 wt % to about 30 wt %, based on a total weight of the hardmask composition.

The solvent may include propylene glycol, propylene glycol diacetate, methoxy propanediol, diethylene glycol, diethylene glycol butylether, tri(ethylene glycol)monomethylether, propylene glycol monomethylether, propylene glycol monomethylether acetate, cyclohexanone, ethyllactate, gamma-butyrolactone, N,N-dimethyl formamide, N,N-dimethyl acetamide, methylpyrrolidone, methylpyrrolidinone, acetylacetone, or ethyl 3-ethoxypropionate.

The embodiments may be realized by providing a hardmask layer including a cured product of the hardmask composition according to an embodiment.

The embodiments may be realized by providing a method of forming patterns, the method including providing a material layer on a substrate; applying the hardmask composition according to an embodiment to the material layer; heat-treating the hardmask composition to form a hardmask layer; forming a photoresist layer on the hardmask layer; exposing and developing the photoresist layer to form a photoresist pattern; selectively removing the hardmask layer using the photoresist pattern to expose a portion of the material layer; and etching an exposed part of the material layer.

Forming the hardmask layer may include heat-treating at a temperature of about 100° C. to about 1,000° C.

### DETAILED DESCRIPTION

Example embodiments will now be described more fully hereinafter; however, they may be embodied in different forms and should not be construed as limited to the embodiments set forth herein. Rather, these embodiments are provided so that this disclosure will be thorough and complete, and will fully convey exemplary implementations to those skilled in the art.

It will also be understood that when a layer or element is referred to as being “on” another layer or element, it can be directly on the other layer or element, or intervening layers may also be present. In addition, it will also be understood that when a layer is referred to as being “between” two layers, it can be the only layer between the two layers, or one or more intervening layers may also be present.

As used herein, when a definition is not otherwise provided, ‘substituted’ may refer to replacement of a hydrogen atom of a compound by a substituent selected from a halogen atom (F, Br, Cl, or I), a hydroxy group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a vinyl group, a C1 to C20 alkyl group, a C2 to C20 alkenyl group, a C2 to C20 alkynyl group, a C6 to C30 aryl group, a C7 to C30 arylalkyl group, a C9 to C30 allylaryl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, or a combination thereof. As used herein, hydrogen substitution (—H) may include deuterium substitution (-D) or tritium substitution (-T). For example, any hydrogen in any compound described herein may be protium, deuterium, or tritium (e.g., based on natural or artificial substitution). As used herein, the term “or” is not necessarily an exclusive term, e.g., “A or B” would include A, B, or A and B.

In addition, adjacent two substituents of the substituted halogen atom (F, Br, Cl, or I), the hydroxy group, the nitro group, the cyano group, the amino group, the azido group, the amidino group, the hydrazino group, the hydrazono group, the carbonyl group, the carbamyl group, the thiol group, the ester group, the carboxyl group or the salt thereof, the sulfonic acid group or the salt thereof, the phosphoric acid or the salt thereof, the C1 to C30 alkyl group, the C2 to C30 alkenyl group, the C2 to C30 alkynyl group, the C6 to C30 aryl group, the C7 to C30 arylalkyl group, the C1 to C30 alkoxy group, the C1 to C20 heteroalkyl group, the C3 to C20 heteroarylalkyl group, the C3 to C30 cycloalkyl group, the C3 to C15 cycloalkenyl group, the C6 to C15 cycloalkynyl group, the C2 to C30 heterocyclic group may be fused to form a ring.

As used herein, the polymer may include both an oligomer and a polymer.

Unless otherwise specified in the present specification, the “weight average molecular weight” is measured by dissolving a powder sample in tetrahydrofuran (THF) and then using 1200 series Gel Permeation Chromatography (GPC) of Agilent Technologies (column is Shodex Company LF-804, standard sample is Shodex company polystyrene).

The hardmask composition according to some embodiments may help increase a carbon content by including a polymer including large aromatic monomolecules or moieties. Accordingly, the etch resistance of the hardmask layer obtained from the composition may be improved, and a high-thickness hardmask layer may be formed. In addition, the polymer may include tertiary carbons, and the polymer may help increase the carbon content in the polymer and at the same time, the multifunctional group may help increase solubility in solvents.

The hardmask composition according to some embodiments may include, e.g., a polymer including a structural unit represented by Chemical Formula 1, and a solvent.

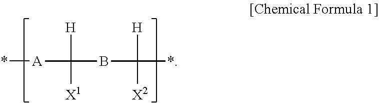

In Chemical Formula 1, A may include, e.g., a moiety represented by Chemical Formula 2.

B may include, e.g., a substituted or unsubstituted moiety of Group 1. As used herein, a substituted or unsubstituted moiety may be unsubstituted, as illustrated, or may include a substituent thereon as described above.

X¹ and X² may each independently include, e.g., a substituted or unsubstituted moiety of Group 2.

* is a linking point:

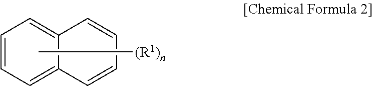

In Chemical Formula 2, R¹ may be or may include, e.g., a hydroxy group, an amine group (—NH₂), a thiol group (—SH), or —OR^{a}, in which R^{a} may be, e.g., a substituted or unsubstituted C1 to C30 alkyl group, a substituted or unsubstituted C2 to C30 alkenyl group, a substituted or unsubstituted C2 to C30 alkynyl group, or a substituted or unsubstituted C6 to C30 aryl group.

n may be, e.g., an integer of 2 to 6.

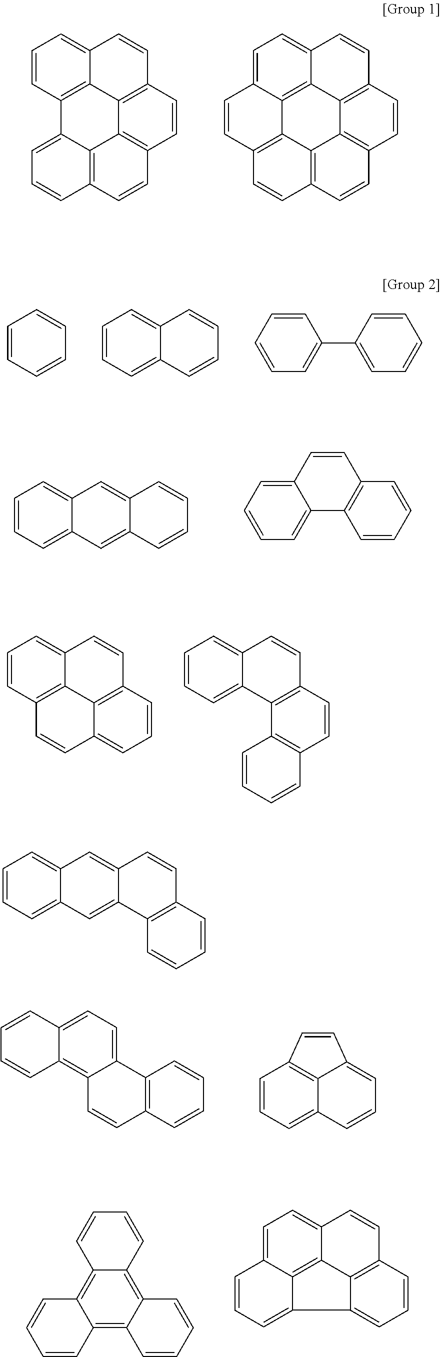

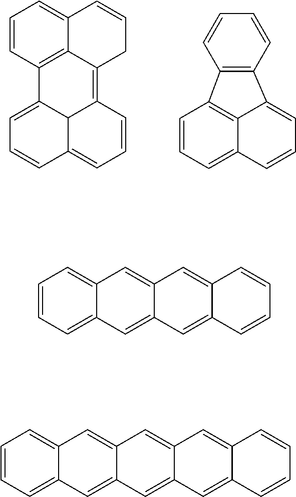

As shown in Chemical Formula 1, the polymer according to some embodiments may include, e.g., an aromatic hydrocarbon such as coronene or benzoperylene and an aromatic hydrocarbon of Chemical Formula 2 or Group 2, thereby increasing the carbon content in the polymer. In an implementation, a thin film formed from a hardmask composition including the polymer has excellent etch resistance and can secure excellent pattern formation properties.

In an implementation, as shown in Chemical Formula 2, the main chain structure of the polymer according to some embodiments may include at least two substituents, so that the solubility of the polymer in a solvent may be improved, and the film density of a hardmask layer formed from a composition including the polymer may be improved. By controlling the number of hydrophilic functional groups, e.g., hydroxy groups or alkoxy groups, in Chemical Formula 2, the solubility of the polymer in the solvent and the film density of the hardmask layer can be adjusted.

In an implementation, R¹ in Chemical Formula 2 may be, e.g., a hydroxy group, an amine group (—NH₂), a thiol group (—SH), or —OR^{a}, in which R^{a} may be, e.g., a substituted or unsubstituted C1 to C20 alkyl group, a substituted or unsubstituted C2 to C20 alkenyl group, a substituted or unsubstituted C2 to C20 alkynyl group, or a substituted or unsubstituted C6 to C20 aryl group. In an implementation, R¹ may be, e.g., a hydroxy group, or —OR^{a}, in which R^{a} may be, e.g., a substituted or unsubstituted C1 to C10 alkyl group, a substituted or unsubstituted C2 to C10 alkenyl group, a substituted or unsubstituted C2 to C10 alkynyl group, or a substituted or unsubstituted C6 to C16 aryl group. In an implementation, R¹ may be, e.g., a hydroxy group, a substituted or unsubstituted C1 to C10 alkoxy group, a substituted or unsubstituted C2 to C10 alkenyloxy group, a substituted or unsubstituted C2 to C10 alkynyloxy group, or a substituted or unsubstituted C6 to C16 aryloxy group. In an implementation, R¹ may be, e.g., a hydroxy group, a substituted or unsubstituted C2 to C5 alkoxy group, or a substituted or unsubstituted C2 to C5 alkynyloxy group.

In an implementation, in Chemical Formula 2, n may be, e.g., an integer of 2 to 6, an integer of 2 to 4, or 2 or 3.

In an implementation, the moiety of Chemical Formula 2 may be, e.g., a moiety represented by Chemical Formula 2-1 or Chemical Formula 2-2.

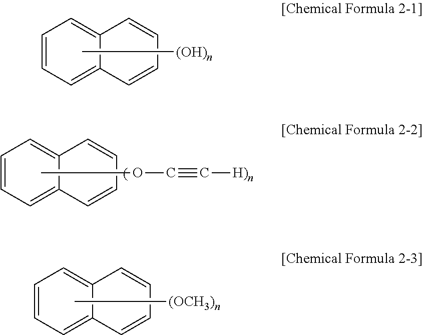

In Chemical Formula 2-1 to Chemical Formula 2-3, n may be, e.g., 2 or 3.

The moiety of B of Chemical Formula 1 may be unsubstituted or substituted. When the moiety of B is substituted, the substituent group may include, e.g., a hydroxy group, a halogen atom, a substituted or unsubstituted C1 to C20 alkoxy group, a substituted or unsubstituted C1 to C20 alkyl group, a substituted or unsubstituted C2 to C20 alkenyl group, a substituted or unsubstituted C2 to C20 alkynyl group, or a combination thereof. In an implementation, the substituent may include, e.g., a hydroxy group, a substituted or unsubstituted C1 to C20 alkoxy group, or a combination thereof, for example a hydroxy group, a methoxy group, an ethoxy group, a propoxy group, a butoxy group, a pentoxy group, or a combination thereof.

In an implementation, in Chemical Formula 1, X¹ and X² may each independently include, e.g., a substituted or unsubstituted moiety of Group 2-1. In an implementation, in Chemical Formula 1, X¹ and X² may each independently include, e.g., a substituted or unsubstituted moiety of Group 2-2.

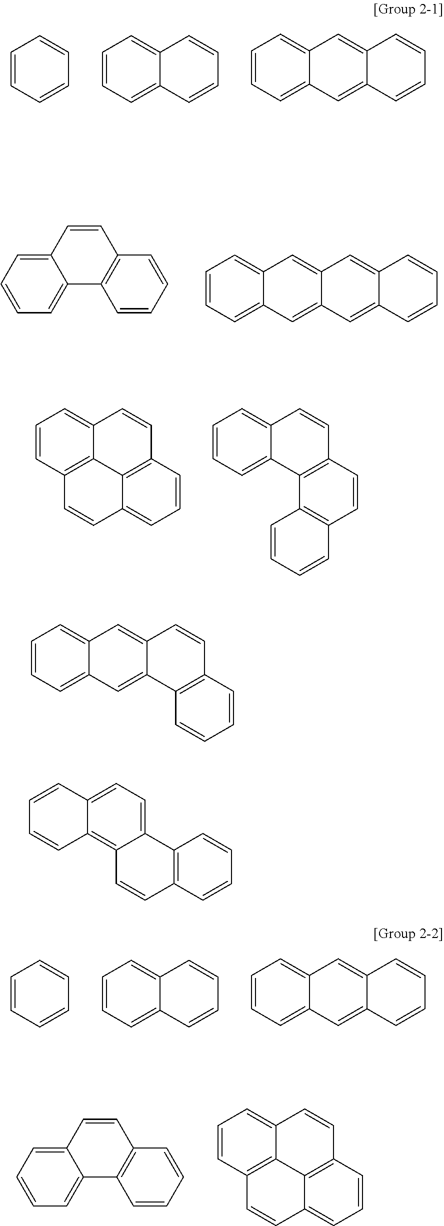

In an implementation, the structural unit represented by Chemical Formula 1 may be represented by, e.g., one of Chemical Formula 1-1 to Chemical Formula 1-6.

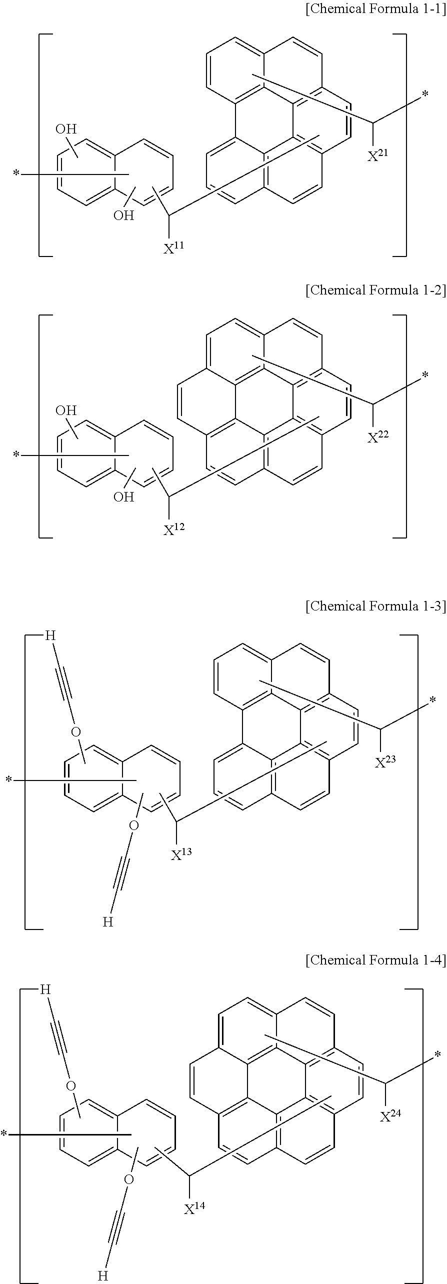

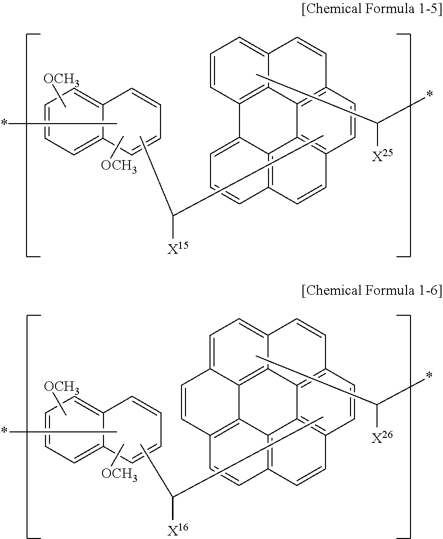

In Chemical Formula 1-1 to Chemical Formula 1-6, X¹¹ to X¹⁶ and X²¹ to X²⁶ may each independently include, e.g., a substituted or unsubstituted moiety of Group 2-2.

In an implementation, the structural unit represented by Chemical Formula 1 may be represented by, e.g., one of Chemical Formula 1-7 to Chemical Formula 1-10, or a combination thereof.

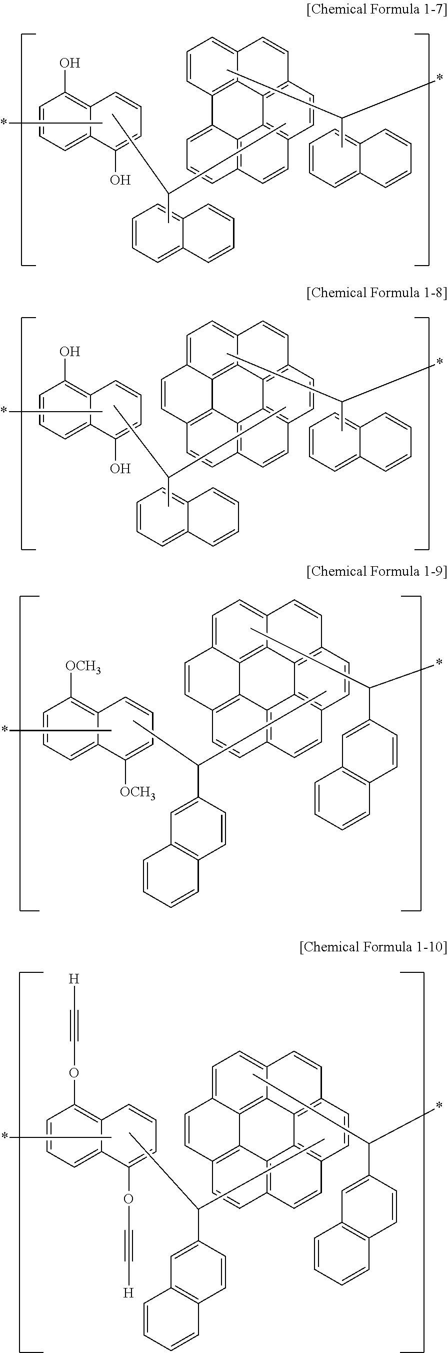

In an implementation, the polymer may have a weight average molecular weight of, e.g., about 1,000 g/mol to about 200,000 g/mol. In an implementation, the polymer may have a weight average molecular weight of, e.g., about 1,000 g/mol to about 150,000 g/mol, about 1,000 g/mol to about 100,000 g/mol, about 1,200 g/mol to about 50,000 g/mol, or about 1,200 g/mol to about 10,000 g/mol. By having a weight average molecular weight within the above ranges, the carbon content and solubility in the solvent of the hardmask composition including the above polymer may be adjusted and optimized.

The polymer may be included in an amount of, e.g., about 0.1 wt % to about 30 wt %, based on a total weight of the hardmask composition. In an implementation, the polymer may be included in an amount of, e.g., about 0.2 wt % to about 30 wt %, about 0.5 wt % to about 30 wt %, about 1 wt % to about 30 wt %, about 1.5 wt % to about 25 wt %, or about 2 wt % to about 20 wt %. By including the polymer within the above ranges, a thickness, a surface roughness, and a planarization degree of the hardmask may be easily adjusted.

The hardmask composition according to some embodiments may include a solvent. In an implementation, the solvent may include, e.g., propylene glycol, propylene glycol diacetate, methoxy propanediol, diethylene glycol, diethylene glycol butyl ether, tri(ethylene glycol) monomethyl ether, propylene glycol monomethyl ether, propylene glycol monomethyl ether acetate, cyclohexanone, ethyl lactate, gamma-butyrolactone, N,N-dimethylformamide, N,N-dimethylacetamide, methylpyrrolidone, methylpyrrolidinone, acetylacetone, ethyl 3-ethoxypropionate, or the like. The solvent may have sufficient solubility and/or dispersibility for the polymer.

In an implementation, the hardmask composition may further include an additive, e.g., a surfactant, a crosslinking agent, a thermal acid generator, or a plasticizer.

The surfactant may include, e.g., a fluoroalkyl-based compound, alkylbenzenesulfonate, alkylpyridinium salt, polyethylene glycol, a quaternary ammonium salt, or the like.

The crosslinking agent may include, e.g., a melamine, a substituted urea, or a polymer crosslinking agent. In an implementation, it may be a crosslinking agent having at least two crosslinking substituents, e.g., methoxymethylated glycoruryl, butoxymethylated glycoruryl, methoxymethylated melamine, butoxymethylated melamine, methoxymethylated benzoguanamine, butoxy methylated benzoguanamine, methoxymethylated urea, butoxymethylated urea, methoxymethylated thiourea, or butoxymethylated thiourea.

In an implementation, as the crosslinking agent, a crosslinking agent having high heat resistance may be used. The crosslinking agent having high heat resistance may include a compound containing a crosslinking substituent having an aromatic ring (e.g., a benzene ring or a naphthalene ring) in the molecule.

The thermal acid generator may include, e.g., an acid compound, such as p-toluenesulfonic acid, trifluoromethanesulfonic acid, pyridinium p-toluenesulfonic acid, salicylic acid, sulfosalicylic acid, citric acid, benzoic acid, hydroxybenzoic acid, naphthalenecarboxylic acid, or 2,4,4,6-tetrabromocyclohexadienone, benzointosylate, 2-nitrobenzyltosylate, or other organic sulfonic acid alkyl esters.

In an implementation, a hardmask layer including a cured product of the aforementioned hardmask composition may be provided.

Hereinafter, a method of forming patterns using the aforementioned hardmask composition is described.

A method of forming patterns according to some embodiments may include providing a material layer on a substrate, applying a hardmask composition including the aforementioned polymer and solvent to the material layer, heat-treating the hardmask composition to form a hardmask layer, forming a photoresist layer on the hardmask layer, exposing and developing the photoresist layer to form a photoresist pattern, selectively removing the hardmask layer using the photoresist pattern to expose a part of the material layer, and etching the exposed part of the material layer.

The substrate may include, e.g., a silicon wafer, a glass substrate, or a polymer substrate. The material layer may be a material to be finally patterned, e.g., a metal layer such as an aluminum layer or a copper layer, a semiconductor layer such as a silicon layer, or an insulation layer such as a silicon oxide layer or a silicon nitride layer. The material layer may be formed through a method such as a chemical vapor deposition (CVD) process.

The hardmask composition may be the same as described above, and may be applied by spin-on coating in a form of a solution. In an implementation, an application thickness of the hardmask composition may be, e.g., about 50 Å to about 200,000 Å.

The heat-treating of the hardmask composition may be performed, e.g., at about 100° C. to about 1,000° C. for about 10 seconds to about 1 hour. In an implementation, the heat-treating of the hardmask composition may include a plurality of heat-treating processes, e.g., a first heat-treating process, and a second heat-treating process.

In an implementation, the heat-treating of the hardmask composition may include, e.g., one heat-treating process performed at about 100° C. to about 1000° C. for about 10 seconds to about 1 hour. In an implementation, the heat-treating may be performed under an atmosphere of air or nitrogen, or an atmosphere having oxygen concentration of 1 wt % or less.

In an implementation, the heat-treating of the hardmask composition may include, e.g., a first heat-treating process performed at about 100° C. to about 1,000° C., about 100° C. to about 800° C., about 100° C. to about 500° C., or about 150° C. to about 400° C. for about 30 seconds to about 1 hour, about 30 seconds to about 30 minutes, about 30 seconds to about 10 minutes, or about 30 seconds to about 5 minutes.

In an implementation, the heat-treating of the hardmask composition may include, e.g., a second heat-treating process performed at about 100° C. to 1,000° C., about 300° C. to about 1,000° C., about 500° C. to about 1,000° C., or about 500° C. to about 600° C. for about 30 seconds to about 1 hour, about 30 seconds to about 30 minutes, about 30 seconds to about 10 minutes, or about 30 seconds to about 5 minutes, consecutively. In an implementation, the first and second heat-treating process may be performed under an air or nitrogen atmosphere, or may be performed in an atmosphere with an oxygen concentration of 1 wt % or less.

By performing at least one of the steps of heat-treating the hardmask composition at a high temperature of 200° C. or higher, high etch resistance capable of withstanding etching gas and chemical liquid exposed in subsequent processes including the etching process may be exhibited.

In an implementation, the forming of the hardmask layer may include a UV/Vis curing process or a near IR curing process.

In an implementation, the forming of the hardmask layer may include at least one of a first heat-treating process, a second heat-treating process, a UV/Vis curing process, and a near IR curing process, or may include two or more processes consecutively.

In an implementation, the method may further include forming a silicon-containing thin layer on the hardmask layer. The silicon-containing thin layer may be formed of, e.g., SiCN, SiOC, SiON, SiOCN, SiC, SiO, SiN, or the like.

In an implementation, the method may further include forming a bottom antireflective coating (BARC) on the silicon-containing thin layer or on the hardmask layer before forming the photoresist layer.

In an implementation, exposure of the photoresist layer may be performed using, e.g., ArF, KrF, or EUV. After exposure, heat-treating may be performed at about 100° C. to about 700° C.

In an implementation, the etching process of the exposed part of the material layer may be performed through a dry etching process using an etching gas and the etching gas may include, e.g., N₂/O₂, CHF₃, CF₄, Cl₂, BCl₃, or a mixed gas thereof.

The etched material layer may be formed in a plurality of patterns, and the plurality of patterns may include a metal pattern, a semiconductor pattern, an insulation pattern, or the like, e.g., diverse patterns of a semiconductor integrated circuit device.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Synthesis of Polymers

### Comparative Synthesis Example 1

In a 500 ml 2-necked flask equipped with a mechanical agitator and a cooling tube, 30.0 g (0.1 mol) of coronene and 34 g (0.2 mol) of 2-naphthoyl chloride were dissolved in 300 g of 1,2-dichloroethane. After 15 minutes, 15 g (0.11 mol) of trichloro aluminum (aluminum chloride, AlCl₃) was slowly added thereto and then, reacted at ambient temperature for 5 hours. After the reaction, the trichloro aluminum was removed by using water, and the residue was concentrated with an evaporator. Subsequently, 160 g of tetrahydrofuran was added to a compound obtained from the concentration to obtain a solution. To the solution, an aqueous solution of 16 g (0.42 mol) of sodium borohydride was slowly added to the solution at ambient temperature and then, stirred for 12 hours. When a reaction was completed, the resultant was acidified to pH 5 with a 7% hydrogen chloride solution and then, extracted with ethyl acetate, and an organic solvent was removed therefrom under a reduced pressure to obtain Compound A represented by Chemical Formula A.

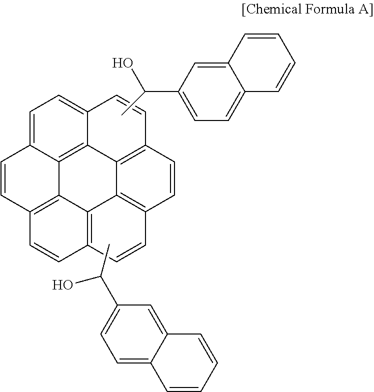

### Comparative Synthesis Example 2

Compound B represented by Chemical Formula B was obtained in the same manner as in Comparative Synthesis Example 1 except that benzoperylene was used instead of the coronene.

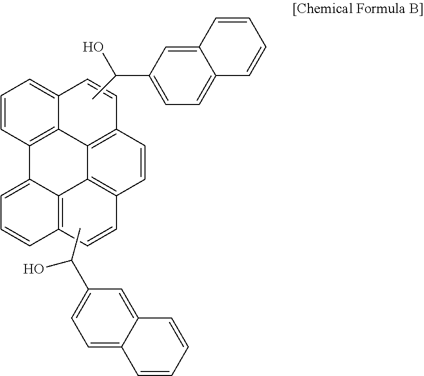

### Comparative Synthesis Example 3

50 g (0.23 mol) of 1-hydroxypyrene and 38.0 g (0.23 mol) of 1,4-bis(methoxymethyl)benzene were sequentially put in a 500 ml flask, and then dissolved in 100 g of propylene glycol monomethyl ether acetate (PGMEA). 4.35 g (0.02 mol) of paratoluenesulfonic acid was added thereto and then, stirred at 100° C. for about 20 hours. The polymerization reaction was completed when a sample taken from the product therefrom at every one hour had a weight average molecular weight of 2,500 g/mol to 2,600 g/mol, to obtain Comparative Polymer C including a structural unit represented by Chemical Formula C. (Mw: 2,500 g/mol, PD: 1.54).

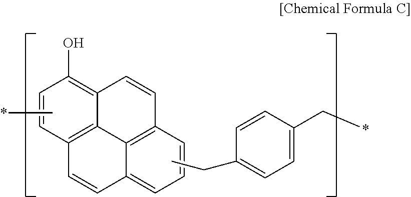

### Comparative Synthesis Example 4

50 g (0.23 mol) of 1-hydroxypyrene and 24.3 g (0.23 mol) of benzaldehyde were sequentially put in a 500 ml flask, and then dissolved in 130 g of propylene glycol monomethyl ether acetate (PGMEA). 13.1 g (0.07 mol) of paratoluenesulfonic acid was added thereto and then, stirred at 110° C. for about 24 hours. The polymerization reaction was completed when a sample taken from the product therefrom at every one hour had a weight average molecular weight of 3,000 g/mol to 3,500 g/mol, to obtain Comparative Polymer D including a structural unit represented by Chemical Formula D. (Mw: 3,400 g/mol, PD: 1.61).

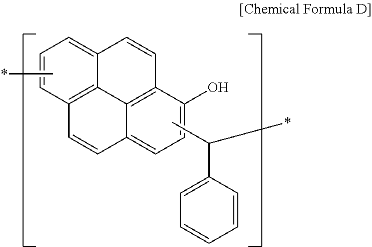

### Comparative Synthesis Example 5

50 g (0.08 mol) of Compound A, 11.2 g (0.08 mol) of 1-naphthol(1-dihydroxynaphthalene), 0.47 g (0.002 mol) of p-toluenesulfonic acid, and 148 g of 1,4-dioxane were put in a 500 ml 2-necked flask equipped with a mechanical agitator and a cooling tube, and then stirred at 70° C. for 24 hours. After the polymerization reaction, the temperature was lowered to 30° C., 300 g of tetrahydrofuran was added thereto to prevent a compound from hardening, and the pH of the reactants was adjusted into 5 to 6 by using a 7% sodium bicarbonate aqueous solution. Subsequently, 1,000 ml of ethyl acetate was added thereto and then, continuously stirred and then, treated through a separatory funnel to extract an organic layer. 500 ml of water was put in the separatory funnel to perform, three or more times, a process of removing acid and a sodium salt and thereby, extract the organic layer. The extracted organic solution was concentrated with an evaporator, and 700 g of tetrahydrofuran was added to a compound obtained by the concentration to obtain a solution of the compound. The solution was slowly added dropwise to a beaker containing 3,000 ml of hexane, while stirring, to form precipitates and thereby, obtain Comparative Polymer E including a structural unit represented by Chemical Formula E.

The polymer was measured with respect to a weight average molecular weight (Mw) and polydispersity (PD) by using gel permeation chromatography (GPC). (Mw: 1,450 g/mol, PD: 1.21)

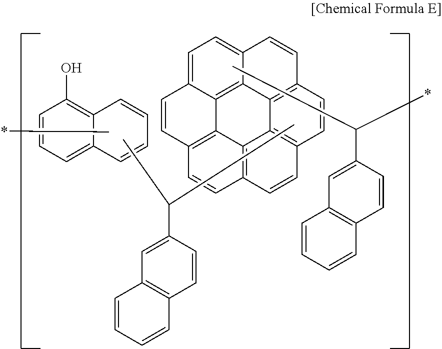

### Comparative Synthesis Example 6

Comparative Polymer F including a structural unit represented by Chemical Formula F was obtained in the same manner as in Comparative Synthesis Example 4 except that 1,5-dihydroxynaphthalene instead of the 1-hydroxypyrene and benzo[ghi]perylene carboxy aldehyde instead of the benzaldehyde were used. The synthesized polymer was measured with respect to a weight average molecular weight (Mw) and polydispersity (PD) by using gel permeation chromatography (GPC). (Mw: 1,600 g/mol, PD: 1.23)

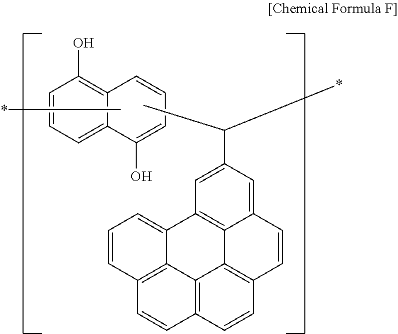

### Synthesis Example 1

50 g (0.08 mol) of Compound A, 13.1 g (0.08 mol) of 1,5-dihydroxynaphthalene, 0.47 g (0.002 mol) of p-toluenesulfonic acid, and 148 g of 1,4-dioxane were put in a 500 ml 2-necked flask equipped with a mechanical agitator and a cooling tube, and then stirred at 70° C. for 24 hours. After the polymerization reaction, the temperature was lowered to 30° C., 300 g of tetrahydrofuran was added thereto to prevent a compound from hardening, and pH of the reactants was adjusted to 5 to 6 by using a 7% sodium bicarbonate aqueous solution. Subsequently, 1,000 ml of ethyl acetate was added thereto and then, continuously stirred and then, treated with a separatory funnel to extract an organic layer. Then, 500 ml of water was added to the separatory funnel to perform, three times, a process of removing acid and a sodium salt and thereby, extract the organic layer. The extracted organic solution was concentrated with an evaporator, and 700 g of tetrahydrofuran was added to a compound obtained by the concentration to obtain a solution of the compound. The solution was slowly added dropwise to a beaker containing 3,000 ml of hexane, while stirring, to form precipitates and thereby, obtain Polymer G including a structural unit represented by Chemical Formula 1-8.

The polymer was measured with respect to a weight average molecular weight (Mw) and Polydispersity (PD) by using Gel permeation chromatography (GPC). (Mw: 2,550 g/mol, PD: 1.64)

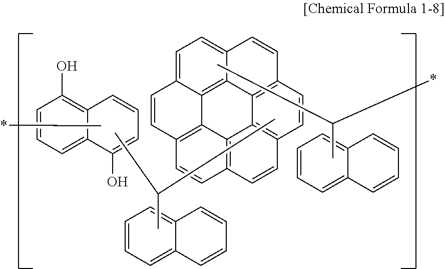

### Synthesis Example 2

Polymer H including a structural unit represented by Chemical Formula 1-7 was obtained in the same manner as in Synthesis Example 1 except that Compound B was used instead of Compound A. The synthesized polymer was measured with respect to a weight average molecular weight (Mw) and polydispersity (PD) by using Gel permeation chromatography (GPC). (Mw: 2,900 g/mol, PD:1.65)

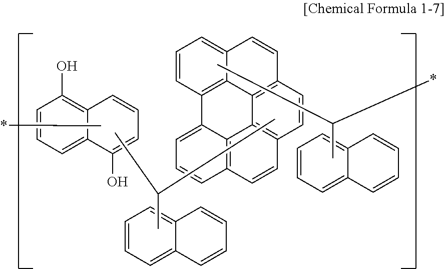

### Synthesis Example 3

Polymer I including a structural unit represented by Chemical Formula 1-9 was obtained in the same manner as in Synthesis Example 1 except that 1-5-dimethoxynaphthalene was used instead of the 1,5-dihydroxynaphthalene. The synthesized polymer was measured with respect to a weight average molecular weight (Mw) and polydispersity (PD) by using Gel permeation chromatography (GPC). (Mw: 2,100 g/mol, PD: 1.45)

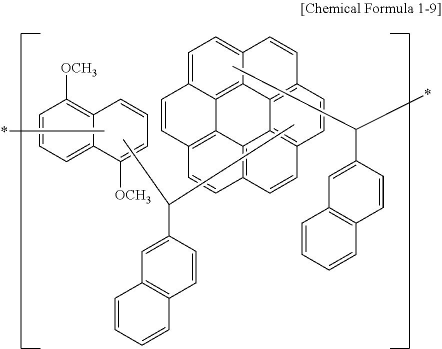

### Synthesis Example 4

Polymer J including a structural unit represented by Chemical Formula 1-10 was obtained in the same manner as in Synthesis Example 1 except that 1-5-diacetyleneoxynaphthalene was used instead of the 1,5-dihydroxynaphthalene. The synthesized polymer was measured with respect to a weight average molecular weight (Mw) and polydispersity (PD) by using Gel permeation chromatography (GPC). (Mw: 1,950 g/mol, PD: 1.37)

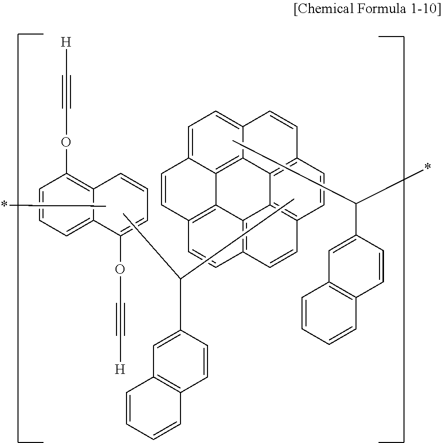

### Preparation of Hardmask Composition

### Example 1

A hardmask composition was prepared by dissolving 1.2 g of Polymer G of Synthesis Example 1 in 10 g of a mixed solvent of propylene glycolmonomethylether acetate (PGMEA) and propylene glycolmonomethylether (PGME) (7:3 (v/v)) and then, filtering the solution with a 0.1 μm TEFLON (tetrafluoroethylene) filter.

### Example 2

A hardmask composition was prepared in the same manner as in Example 1 except that Polymer H was used instead of Polymer G.

### Example 3

A hardmask composition was prepared in the same manner as in Example 1 except that Polymer I was used instead of Polymer G.

### Example 4

A hardmask composition was prepared in the same manner as in Example 1 except that Polymer J was used instead of Polymer G.

### Comparative Example 1

A hardmask composition was prepared by dissolving 1.5 g of Compound A of Comparative Synthesis Example 1 in 10 g of a mixed solvent of propylene glycolmonomethylether acetate (PGMEA) and cyclohexanone (7:3(v/v)) and then, filtering the solution with a 0.1 μm TEFLON (tetrafluoroethylene) filter.

### Comparative Example 2

A hardmask composition was prepared in the same manner as in Comparative Example 1 except that Compound B was used instead of Compound A.

### Comparative Example 3

A hardmask composition was prepared in the same manner as in Comparative Example 1 except that Comparative Polymer C was used instead of Compound A.

### Comparative Example 4

A hardmask composition was prepared in the same manner as in Comparative Example 1 except that Comparative Polymer D was used instead of Compound A.

### Comparative Example 5

A hardmask composition was prepared in the same manner as in Comparative Example 1 except that Comparative Polymer E was used instead of Compound A.

### Comparative Example 6

A hardmask composition was prepared in the same manner as in Comparative Example 1 except that Comparative Polymer F was used instead of Compound A.

### Evaluation 1: Etch Resistance Evaluation

Each of the hardmask compositions of Examples 1 to 4 and Comparative Examples 1 to 6 was spin-on coated on a silicon wafer and heat-treated on a hot plate at 400° C. for 2 minutes to form a 4,000 Å-thick thin film. The thin film was measured with respect to a thickness by using a thickness meter made by K-MAC Co., Ltd. After dry-etching the thin film by using CF₄/CHF₃ mixed gas for 100 seconds, the thin film was measured again with respect to a thickness. The thicknesses of the thin film before and after the dry etching were used to calculate a bulk etch rate (BER) according to Calculation Equation 1.

Bulk etch rate (BER)=(initial thin film thickness−thin film thickness after etching)/etching time (Å/s) [Calculation Equation 1]

The results are shown in Table 1.

TABLE 1

| | Bulk etch rate (Å/s) |
|---|---|
| | CF₃/CHF₄ mixed gas |
| Example 1 | 24.0 |
| Example 2 | 24.5 |
| Example 3 | 24.2 |
| Example 4 | 23.9 |
| Comparative Example 1 | 25.2 |
| Comparative Example 2 | 25.5 |
| Comparative Example 3 | 26.1 |
| Comparative Example 4 | 30.3 |
| Comparative Example 5 | 24.9 |
| Comparative Example 6 | 26.0 |

Referring to Table 1, the thin films formed of the hardmask compositions of Examples 1 to 4 exhibited excellent etch resistance to etching gas, compared with the thin films formed of the hardmask compositions according to Comparative Examples 1 to 6.

### Evaluation 2: Solubility Evaluation

Each of the compounds or the polymers of Synthesis Examples 1 to 4 and Comparative Synthesis Examples 1 to 6 was dissolved in 20 g of propylene glycol monomethyl ether acetate (PGMEA). Solubility was calculated by measuring an amount of each of the compounds or the polymers dissolved in 20 g of the solvent and converting it to a percentage.

Solubility (%)−(Amount of dissolved compound or polymer (g)/Amount of solvent (20 g)) [Calculation Equation 2]

The results are shown in Table 2.

TABLE 2

| | Solubility (%) |
|---|---|
| Synthesis Example 1 | 33 |
| Synthesis Example 2 | 37 |
| Synthesis Example 3 | 29 |
| Synthesis Example 4 | 40 |
| Comparative Synthesis Example 1 | 1 |
| Comparative Synthesis Example 2 | 2 |
| Comparative Synthesis Example 3 | 4 |
| Comparative Synthesis Example 4 | 5 |
| Comparative Synthesis Example 5 | 2 |
| Comparative Synthesis Example 6 | 8 |

Referring to Table 2, the polymers of Synthesis Examples 1 to 4 exhibited excellent solubility in the solvent, compared with the compounds or the polymers of Comparative Synthesis Examples 1 to 6.

### Evaluation 3: Storage Stability Evaluation

The hardmask compositions of Examples 1 to 4 and Comparative Examples 1 to 6 were blocked from far ultraviolet rays and stored in an oven at 40° C. for one month and then, examined with respect to changes by using gel permeation chromatography (GPC). When there were no changes (greater than or equal to 10% to an initial level) in a GPC trend curve and a molecular weight, ‘X’ was given, but when there were changes, ‘◯’ was given. The results are shown in Table 3.

TABLE 3

| | Storage stability |
|---|---|
| Example 1 | ◯ |
| Example 2 | ◯ |
| Example 3 | ◯ |
| Example 4 | ◯ |
| Comparative Example 1 | X |
| Comparative Example 2 | X |
| Comparative Example 3 | X |
| Comparative Example 4 | X |
| Comparative Example 5 | X |
| Comparative Example 6 | ◯ |

Referring to Table 3, Examples 1 to 4 exhibited no changes in the trend curves (◯), and Comparative Examples 1 to 5 exhibited changes in the trend curves (X). The hardmask compositions of the Examples exhibited excellent storage stability, compared with the hardmask compositions of Comparative Examples 1 to 5.

### Evaluation 4: Film Density Evaluation

Each of the hardmask compositions of Examples 1 to 4 and Comparative Examples 1 to 6 was spin-on coated on a silicon wafer and then, heat treated on a hot plate at 400° C. for 2 minutes to form a 4,000 Å-thick thin film. The thin film was measured with respect to film density by X-ray diffraction equipment made by Malvern Panalytical Ltd. The results are shown in Table 4.

TABLE 4

| | Film density (g/cm³) |
|---|---|
| Example 1 | 1.36 |
| Example 2 | 1.38 |
| Example 3 | 1.35 |
| Example 4 | 1.42 |
| Comparative Example 1 | 1.25 |
| Comparative Example 2 | 1.28 |
| Comparative Example 3 | 1.24 |
| Comparative Example 4 | 1.34 |
| Comparative Example 5 | 1.25 |
| Comparative Example 6 | 1.30 |

Referring to Table 4, the thin films of the hardmask compositions of Examples 1 to 4 exhibited excellent density, compared with the thin films of the hardmask compositions of Comparative Examples 1 to 6.

By way of summation and review, there is a constant trend in a semiconductor industry to reduce a size of chips. To respond to this, the line width of the resist patterned in lithography technology may have a size of, e.g., several tens of nanometers. A height that can withstand the line width of the resist pattern may be limited, and there are cases where the resists may not have sufficient resistance in the etching step. In order to compensate for this, an auxiliary layer, which is called a hardmask layer, may be used between a material layer to be etched and a photoresist layer. This hardmask layer may serve as an interlayer that transfers a fine pattern of the photoresist through selective etching. The hardmask layer may have etch resistance and crosslinking characteristics to withstand the etching process required for pattern transfer.

Some hardmask layers may be formed in a chemical or physical deposition method and may have low economic efficiency due to a large-scale equipment and a high process cost. A spin-coating technique for forming a hardmask layer has been considered. The spin-coating technique may be an easier process to conduct than some other methods, and a hardmask layer formed therefrom may exhibit excellent gap-fill characteristics and planarization characteristics. In the hardmask layer formed using the spin-coating technique, the etch resistance could be somewhat lowered. A hardmask composition may be applied by the spin-coating technique and may help secure equivalent etch resistance to that of the hardmask layer formed in the chemical or physical deposit method.

In order to improve the etch resistance of a hardmask layer, research on maximizing a carbon content of the hardmask composition is being made. As a carbon content of a polymer included in the hardmask composition is maximized, solubility of the compound in a solvent may tend to decrease. A carbon content of the polymer included in the hardmask composition may be maximized to improve the etch resistance of the hardmask layer formed therefrom, and the polymer may be well soluble in the solvent.

One or more embodiments may provide a hardmask composition that can be effectively applied to a hardmask layer.

One or more embodiments may provide a hardmask composition, a hardmask layer including a cured product of the hardmask composition, and a method of forming patterns using the hardmask composition.

The hardmask composition according to some embodiments may have excellent solubility in solvents and can be effectively applied to a hardmask layer.

A hardmask layer formed from the hardmask composition according to some embodiments may help secure excellent etch resistance and excellent film density.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A hardmask composition, comprising:
a polymer including a structural unit represented by Chemical Formula 1; and
a solvent: 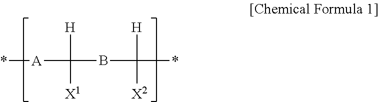
wherein, in Chemical Formula 1,
A includes a moiety represented by Chemical Formula 2,
B includes a substituted or unsubstituted moiety of Group 1,
X¹ and X² each independently include a substituted or unsubstituted moiety of Group 2, and
* is a linking point, 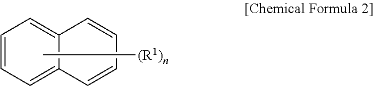
wherein, in Chemical Formula 2,
R¹ is a hydroxy group, an amine group, a thiol group, or —OR®, in which R^{a} is a substituted or unsubstituted C1 to C30 alkyl group, a substituted or unsubstituted C2 to C30 alkenyl group, a substituted or unsubstituted C2 to C30 alkynyl group, or a substituted or unsubstituted C6 to C30 aryl group, and
n is an integer of 2 to 6,

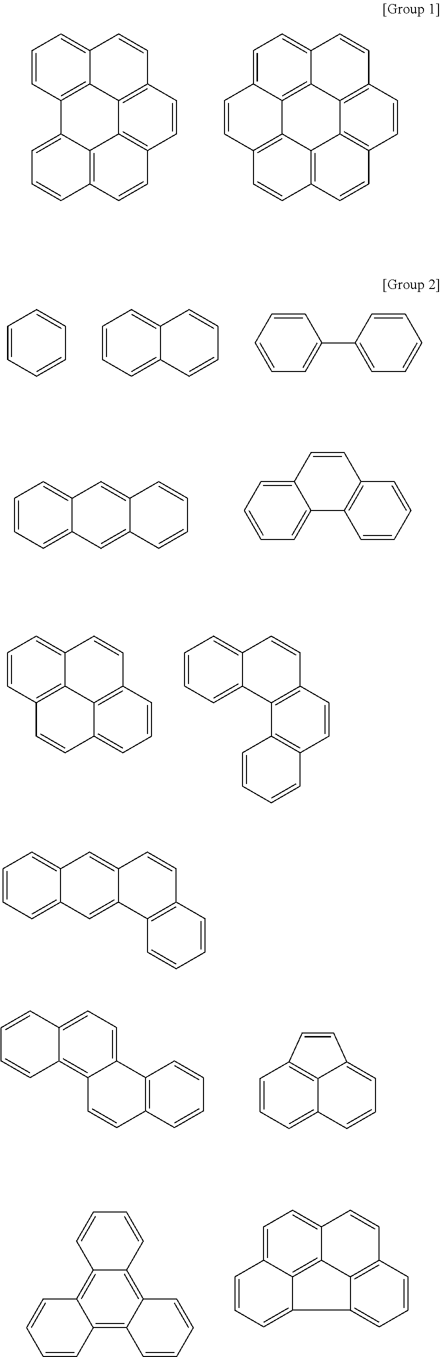

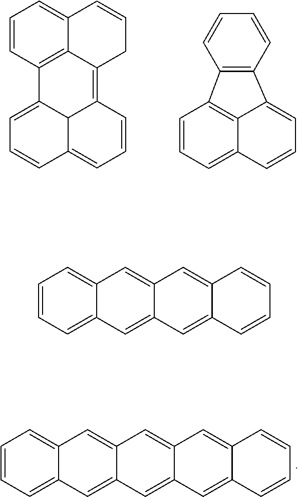

2. The hardmask composition as claimed in claim 1, wherein, in Chemical Formula 2:
R¹ is a hydroxy group, an amine group, a thiol group, or —OR^{a}, in which, R^{a} is a substituted or unsubstituted C1 to C20 alkyl group, a substituted or unsubstituted C2 to C20 alkenyl group, a substituted or unsubstituted C2 to C20 alkynyl group, or a substituted or unsubstituted C6 to C20 aryl group, and
n is an integer of 2 to 4.

3. The hardmask composition as claimed in claim 1, wherein, in Chemical Formula 2:
R¹ is a hydroxy group or —OR^{a}, in which R^{a} is a substituted or unsubstituted C1 to C10 alkyl group, a substituted or unsubstituted C2 to C10 alkenyl group, a substituted or unsubstituted C2 to C10 alkynyl group, or a substituted or unsubstituted C6 to C16 aryl group, and
n is 2 or 3.

4. The hardmask composition as claimed in claim 1, wherein:
A of Chemical Formula 1 includes a moiety represented by one of Chemical Formula 2-1 to Chemical Formula 2-3: 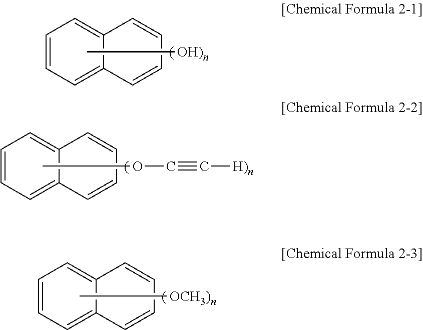
in Chemical Formula 2-1 to Chemical Formula 2-3, n is 2 or 3.

5. The hardmask composition as claimed in claim 1, wherein B of Chemical Formula 1 includes an unsubstituted moiety of Group 1.

6. The hardmask composition as claimed in claim 1, wherein:
B of Chemical Formula 1 includes a substituted moiety of Group 1, and
a substituent of the substituted moiety of Group 1 includes a hydroxy group, a halogen atom, a substituted or unsubstituted C1 to C20 alkoxy group, a substituted or unsubstituted C1 to C20 alkyl group, a substituted or unsubstituted C2 to C20 alkenyl group, a substituted or unsubstituted C2 to C20 alkynyl group, or a combination thereof.

7. The hardmask composition as claimed in claim 1, wherein, in Chemical Formula 1, X¹ and X² each independently include a substituted or unsubstituted moiety of Group 2-1:

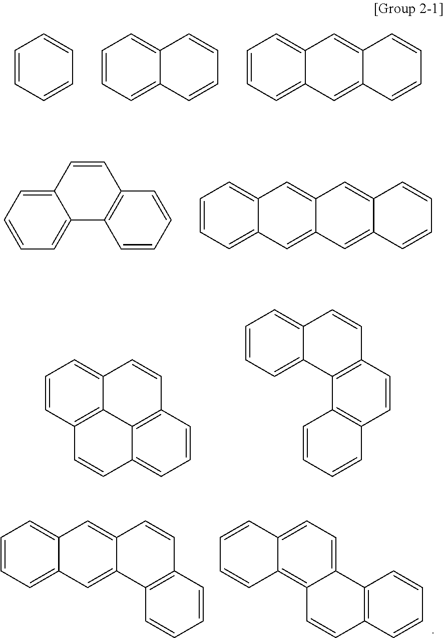

8. The hardmask composition as claimed in claim 1, wherein, in Chemical Formula 1, X¹ and X² each independently include a substituted or unsubstituted moiety of Group 2-2:

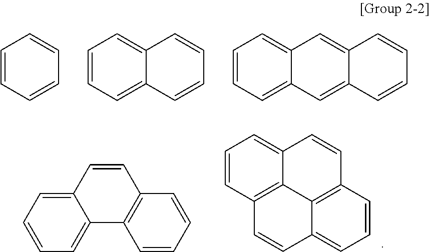

9. The hardmask composition as claimed in claim 1, wherein:
the structural unit represented by Chemical Formula 1 is represented by one of Chemical Formula 1-1 to Chemical Formula 1-6: 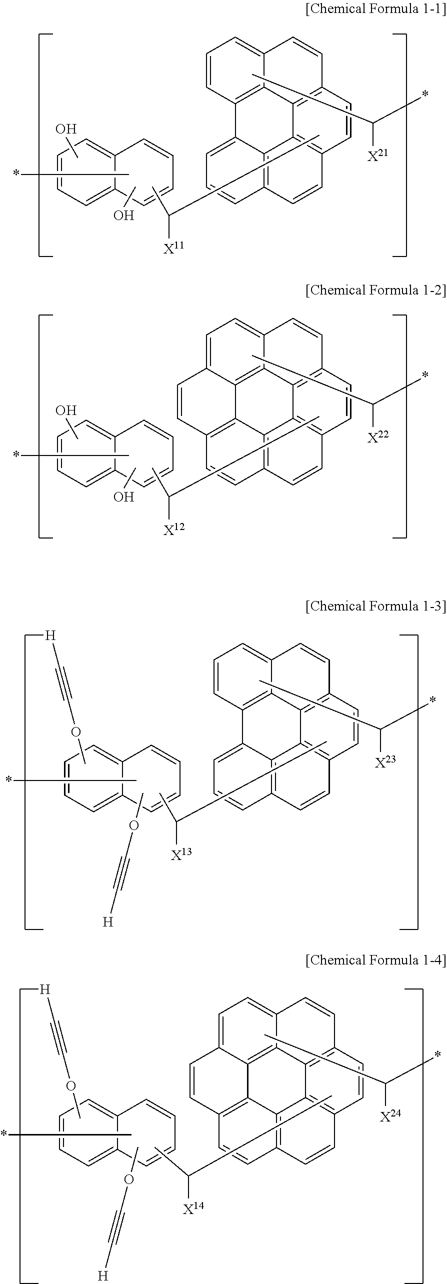 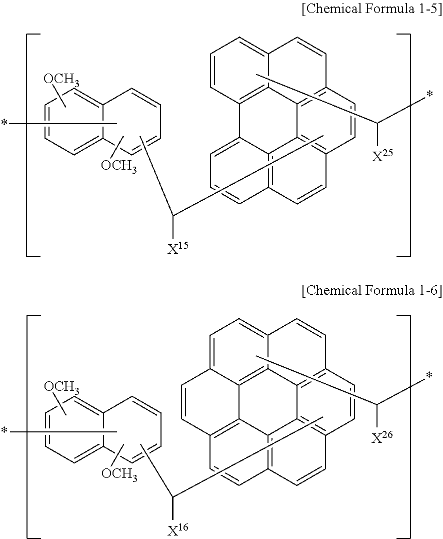
in Chemical Formula 1-1 to Chemical Formula 1-6,
X¹¹ to X¹⁶ and X²¹ to X²⁶ each independently include a substituted or unsubstituted moiety of Group 2-2:

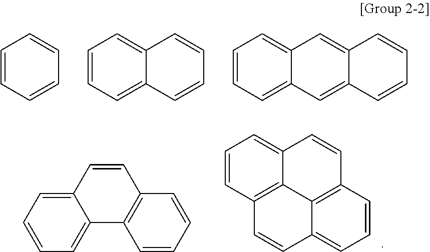

10. The hardmask composition as claimed in claim 1, wherein the structural unit represented by Chemical Formula 1 is represented by one of Chemical Formula 1-7 to Chemical Formula 1-10:

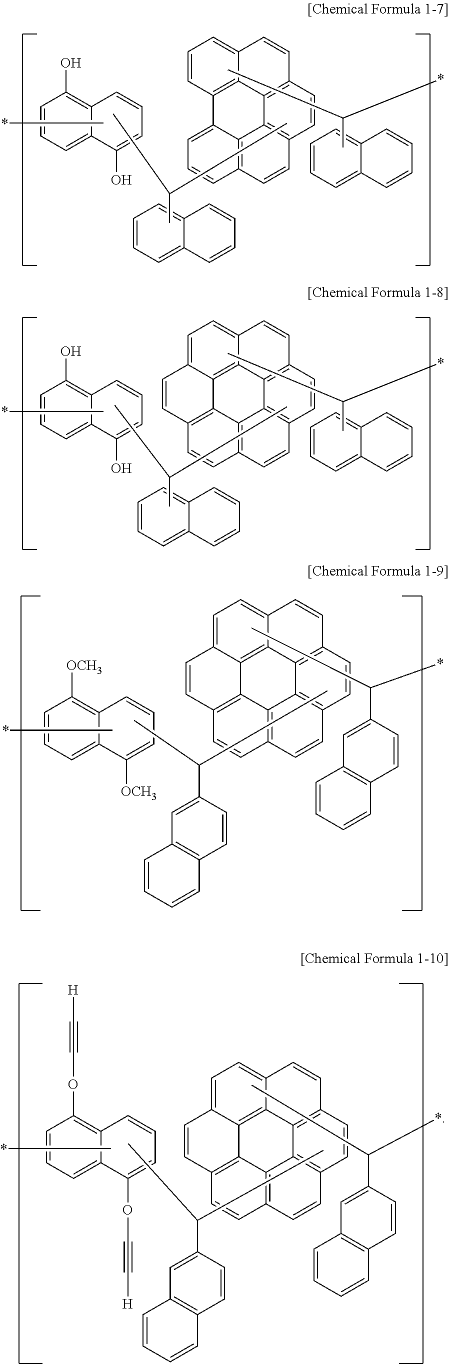

11. The hardmask composition as claimed in claim 1, wherein the polymer has a weight average molecular weight of about 1,000 g/mol to about 200,000 g/mol.

12. The hardmask composition as claimed in claim 1, wherein the polymer is included in an amount of about 0.1 wt % to about 30 wt %, based on a total weight of the hardmask composition.

13. The hardmask composition as claimed in claim 1, wherein the solvent includes propylene glycol, propylene glycol diacetate, methoxy propanediol, diethylene glycol, diethylene glycol butylether, tri(ethylene glycol)monomethylether, propylene glycol monomethylether, propylene glycol monomethylether acetate, cyclohexanone, ethyllactate, gamma-butyrolactone, N,N-dimethyl formamide, N,N-dimethyl acetamide, methylpyrrolidone, methylpyrrolidinone, acetylacetone, or ethyl 3-ethoxypropionate.

14. A hardmask layer comprising a cured product of the hardmask composition as claimed in claim 1.

15. A method of forming patterns, the method comprising:
providing a material layer on a substrate;
applying the hardmask composition as claimed in claim 1 to the material layer;
heat-treating the hardmask composition to form a hardmask layer;
forming a photoresist layer on the hardmask layer,
exposing and developing the photoresist layer to form a photoresist pattern;
selectively removing the hardmask layer using the photoresist pattern to expose a portion of the material layer, and
etching an exposed part of the material layer.

16. The method as claimed in claim 15, wherein forming the hardmask layer includes heat-treating at a temperature of about 100° C. to about 1,000° C.
